(19) United States
(12) Patent Application Publication
(10) Pub. No.: US 2010/0073040 A1
(43) Pub. Date: Mar. 25, 2010

(54) FREQUENCY DIVIDER USING LATCH STRUCTURE

(75) Inventors: Byeong Hak JO, Suwon (KR); Yoo Sam NA, Seoul (KR)

Correspondence Address: LOWE HAUPTMAN HAM & BERNER, LLP, 1700 DIAGONAL ROAD, SUITE 300, ALEXANDRIA, VA, 22314, US

(73) Assignee: Samsung Electro-Mechanics Co., Ltd., SUWON (KR)

(21) Appl. No.: 12/472,870

(22) Filed: May 27, 2009

(30) Foreign Application Priority Data
Sep. 23, 2008 (KR) 10-2008-0093405

(51) Int. Cl. H03B 19/00; G11C 27/02

(52) U.S. Cl. 327/117; 327/91

(57) ABSTRACT

There is provided a frequency divider using a latch structure including: a first latch sampling and latching an input signal in response to a first clock signal and a second clock signal having an inverse phase with respect to the first clock signal; a second latch toggled with the first latch, the second latch sampling and latching the input signal in response to the first and second clock signals; a bias adjustor generating a sampling bias current and a latching bias current to supply to the first and second latches, respectively and adjusting a relative ratio between the sampling bias current and the latching bias current to vary a minimum power point oscillating frequency of the first and second latches.

### CROSS-REFERENCE TO RELATED APPLICATIONS

This application claims the priority of Korean Patent Application No. 2008-0093405 filed on Sep. 23, 2008, in the Korean Intellectual Property Office, the disclosure of which is incorporated herein by reference.

### BACKGROUND OF THE INVENTION

1. Field of the Invention

The present invention relates to a frequency divider using a latch structure, and more particularly, to a frequency divider dividing a frequency by two using a latch structure, in which a ratio between a sampling pair current and a latching pair current is changed using a bias current to change an operating frequency and which also operates in a wide range and occupies much less space and consumes much less current.

2. Description of the Related Art

In general, a telecommunication or a broadcasting system includes a phase-locked loop (PLL) to control a phase of a transmitting frequency or a receiving frequency more accurately. The PLL includes a frequency divider dividing a frequency of a signal by two, which will be described with FIG. 1.

FIG. 1 is a conceptual view illustrating operation of a conventional frequency divider.

The frequency divider 1 shown in FIG. 1 divides a frequency by two and is generally referred to as a prescaler. These divide-by-two circuits (DTCs) such as a prescaler divide the frequency by half.

The divide-by-two frequency divider forms a D-type flip flop by employing two first and second latches 11 and 12. To this end, out of the first and second latches 11 and 12, an output Q of the second latch 12 is connected to an input DB of the first latch 11 to be toggled with each other.

FIG. 2 is a circuit configuration view illustrating a conventional frequency divider.

FIG. 2 is a configuration view illustrating a conventional frequency divider. Referring to FIG. 2, the frequency divider includes a first latch 11 and a second latch 12. The first latch transitions or latches each of outputs XQ and XQB in response to a first clock CLK and a second clock CLKB. The second latch 12 transitions or latches each of outputs YQ and YQB in response to the second clock CLKB and the first clock CLK.

FIG. 3 is a timing chart illustrating major signals of the frequency divider of FIG. 2. Referring to FIG. 3, when the first clock signal CLK is connected to a first clock CK terminal of the first latch 11 and a second clock CKB terminal of the second latch 12, respectively, the first latch 11 transitions the level of the each output XQ and XQB at a rising edge of the first clock signal CLK. That is, out of the first outputs, when XQ transitions from a high level to a low level, XQB transitions from a low level to a high level. On the contrary, out of the first outputs, when XQ transitions from a low level to a high level, XQB transitions from a high level to a low level. At the same time, the second latch 12 latches the each output YQ and YQB.

Next, the second latch 12 performs transitions on the level of the each output YQ and YQB at a falling edge of the first clock signal CLK. That is, out of the second outputs, when YQ transitions from a high level to a low level, YQB transitions from a low level to a high level. On the contrary, out of the second outputs, when YQ transitions from a low level to a high level, YQB transitions from a high level to a low level. At the same time, the first latch 10 latches the each output XQ and XQB.

As described above, when the first clock CLK has a high level, the first latch 11 operates and the output XQ of the first latch 11 becomes equal to the input D. Also, when the first clock signal CLK is a low level, the second latch 12 operates and the output YQ of the second latch 12 becomes equal to the input D.

The conventional frequency divider may operate with a minimum powder at one frequency but not at the other frequencies. In this case, the conventional frequency divider, when applied to a system utilizing a plurality of frequencies, is considerably degraded in power efficiency, and may be required to additionally employ a buffer circuit to increase a magnitude of an input signal of the frequency divider, or several frequency dividers may be employed. To overcome these drawbacks, an operation frequency should be varied.

Accordingly, in this frequency divider with a latch structure, the operation frequency may be varied as follows. The first latch 11 and the second latch 12 of the frequency divider each include a sampling pair sampling a signal and a latching pair latching the sampled signal. The frequency divider adjusts a ratio between a sampling pair current flowing in the sampling pair and a latching pair current flowing in the latching pair to change an operating frequency.

In the conventional frequency divider of a latch structure, to adjust a ratio between the sampling pair current and the latching pair current, a plurality of parallel-connected transistors connected from the sampling pair to a ground and a plurality of parallel connection transistors connected from the latching pair to the ground are controlled to be turned on/off. This allows for adjustment in a ratio between the sampling pair current flowing in the sampling pair and the latching pair current flowing in the latching pair.

However, to adjust an operating frequency, the conventional frequency divider of a latching structure entails a complex structure resulting from parallel connection of a plurality of transistors or use of a capacitor. This may add to the size of the frequency divider.

### SUMMARY OF THE INVENTION

An aspect of the present invention provides a frequency divider dividing a frequency by two using a latch structure, in which a ratio between a sampling pair current and a latching pair current is changed using a bias current to change an operating frequency and which also operates in a wide range and occupies much less space and consumes much less current.

According to an aspect of the present invention, there is provided a frequency divider using a latch structure including: a first latch sampling and latching an input signal in response to a first clock signal and a second clock signal having an inverse phase with respect to the first clock signal; a second latch toggled with the first latch, the second latch sampling and latching the input signal in response to the first and second clock signals; a bias adjustor generating a sampling bias current and a latching bias current to supply to the first and second latches, respectively and adjusting a relative ratio between the sampling bias current and the latching bias current to vary a minimum power point oscillating frequency of the first and second latches.

The first latch may include: a first sampling pair sampling the input signal in response to the first clock signal; a first latching pair latching the input signal from the first sampling pair in response to the second clock signal and outputting an output signal; and a first current adjustor adjusting a ratio between a first current flowing in the first sampling pair and a second current flowing in the first latching pair according to the relative ratio between the sampling bias current and the latching bias current to vary the minimum power point oscillating frequency.

The second latch may include: a second sampling pair sampling and outputting the input signal in response to the second clock signal; a second latching pair latching the input signal from the second sampling pair in response to the first clock signal and outputting an output signal; and a first current adjustor adjusting a third current flowing in the second sampling pair and a fourth current flowing in the second latching pair according to the relative ratio between the sampling bias current and the latching bias current and varying the minimum power point oscillation frequency.

The bias adjustor may preset a reference current and the reference current is set to a sum of the sampling bias current and the latching bias current.

The bias adjustor may be configured such that the latching bias current is varied by varying the sampling bias current.

The bias adjustor may be configured such that the sampling bias current is set greater than the latching bias current to increase the minimum power point oscillating frequency and the sampling bias current is set smaller than the latching bias current to reduce the minimum power point oscillating frequency.

The first sampling pair may include a first transistor pair including first and second transistors, the first and second transistors having drains connected to operating voltage terminals through resistors, respectively and configured as a differential pair, wherein the first transistor transfers an input signal inputted to a gate in response to the first clock signal to the drain of the second transistor, and the second transistor transfers the input signal inputted to the gate in response to the first clock signal to the drain of the first transistor.

The first latching pair may include a second transistor pair including a third transistor having a drain connected to the drain of the first transistor and a fourth transistor having a drain connected to the drain of the second transistor, the third and fourth transistors configured as a cross-coupled pair, wherein a signal inputted through the drain of the third transistor is transferred to a gate of the fourth transistor and a signal inputted through the drain of the fourth transistor is transferred to a gate of the third transistor.

The second sampling pair may include a third transistor pair including fifth and sixth transistors, the fifth and sixth transistors having drains connected to operating voltage terminals through resistors, respectively and configured as a differential pair, wherein the fifth transistor transfers an input signal inputted to a gate in response to the first clock signal to the drain of the sixth transistor, and the sixth transistor transfers the input signal inputted to the gate in response to the first clock signal to the drain of the fifth transistor.

The second latching pair may include a fourth transistor pair including a seventh transistor having a drain connected to the drain of the fifth transistor and an eighth transistor having a drain connected to the drain of the sixth transistor, the seventh and eighth transistors configured as a cross-coupled pair, wherein a signal inputted through the drain of the seventh transistor is transferred to a gate of the eighth transistor and a signal inputted through the drain of the eighth transistor is transferred to a gate of the seventh transistor.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a conceptual view illustrating operation of a conventional frequency divider;

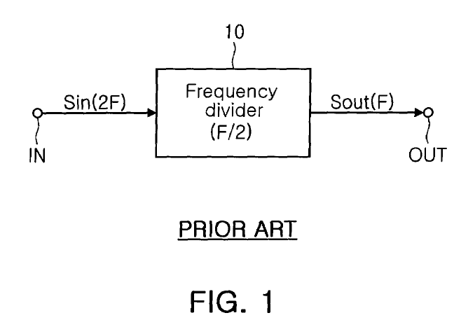

FIG. 2 is a circuit configuration view illustrating a conventional frequency divider;

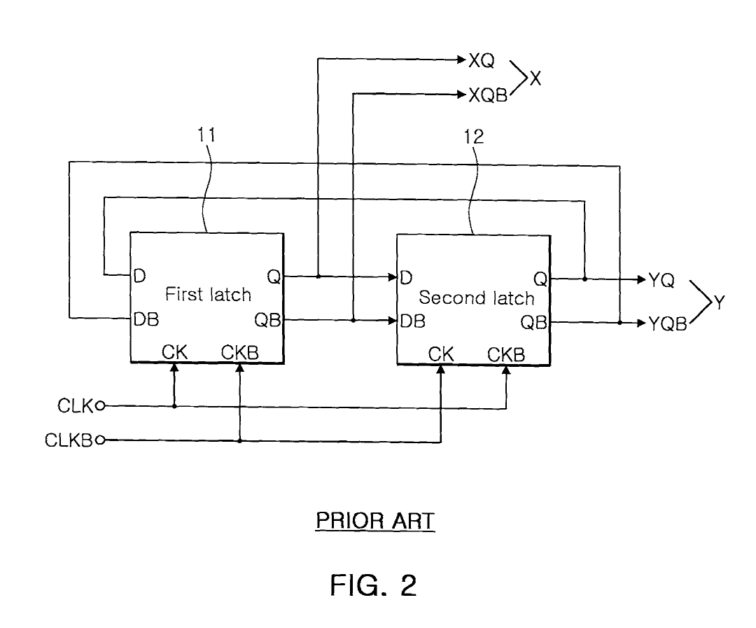

FIG. 3 is a timing chart illustrating major signals of the frequency divider of FIG. 2;

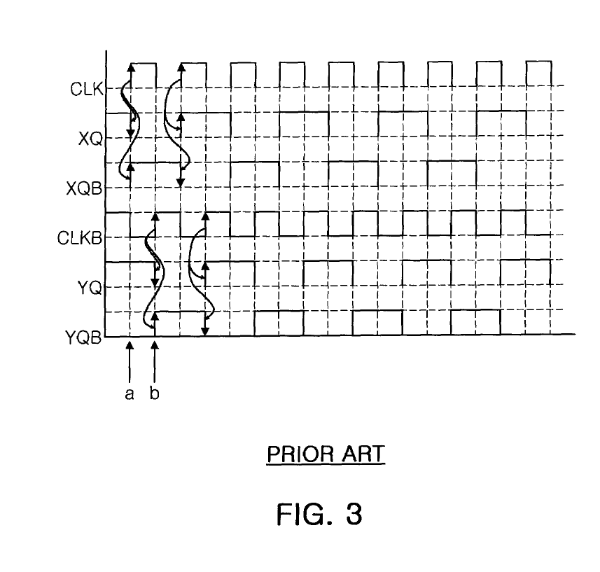

FIG. 4 is a circuit block diagram illustrating a frequency divider according to an exemplary embodiment of the invention;

FIG. 5 is a multiple sensitivity curve illustrating a frequency divider according to an exemplary embodiment of the invention; and

FIG. 6 is a graph illustrating an adjustment range of a sampling bias current and a variable range of a frequency according to an exemplary embodiment of the invention.

### DETAILED DESCRIPTION OF THE PREFERRED EMBODIMENT

Exemplary embodiments of the present invention will now be described in detail with reference to the accompanying drawings. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the shapes and dimensions may be exaggerated for clarity, and the same reference signs are used to designate the same or similar components throughout.

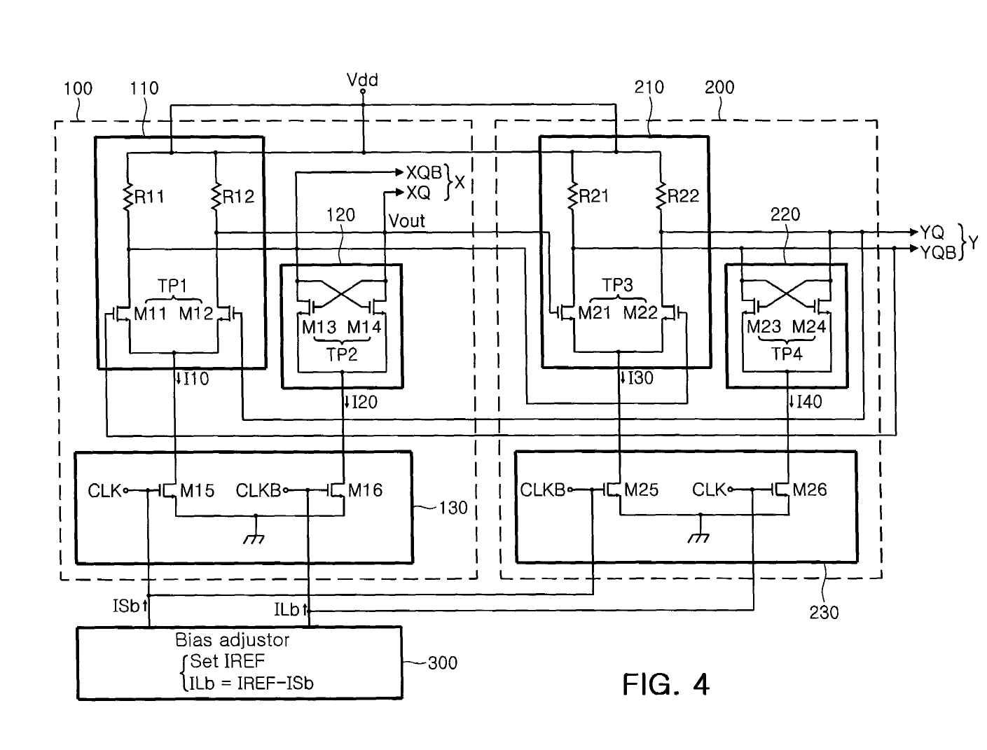

FIG. 4 is a circuit block diagram illustrating a frequency divider according to an exemplary embodiment of the invention.

Referring to FIG. 4, the frequency divider of the present invention includes a first latch 100, a second latch 200 and a bias adjustor 300. The first latch 100 samples and latches an input signal in response to a first clock signal CLK and a second clock signal CLKB having an inverse phase with respect to the first clock signal CLK. The second latch 200 is toggled with the first latch 100, and samples and latches the input signal in response to the first clock signal CLK and the second clock signal CLKB. The bias adjustor 300 generates a sampling bias current ISb and a latching bias current ILb to supply to the first latch 100 and the second latch 200, respectively and adjusts a relative ratio between the sampling bias current ISb and the latching bias current ILb to vary a minimum power point oscillating frequency of the first latch 100 and the second latch 200.

The first latch 100 includes a first sampling pair 110, a first latching pair 120 and a first current adjustor 130. The first sampling pair 110 samples the input signal in response to the first clock signal CLK. The first latching pair 120 latches the input signal from the first sampling pair 110 in response to the second clock signal CLKB and outputs an output signal X; XQ, XQB. The first current adjustor 130 adjusts a ratio between a first current I10 flowing in the first sampling pair 110 and a second current I20 flowing in the first lapping pair 120 according to the relative ratio between the sampling bias current ISb and the latching bias current ILb to vary the minimum power point oscillating frequency.

The second latch 200 includes a second sampling pair 210, a second latching pair 220 and a first current adjustor 230. The second sampling pair 210 samples and outputs the input signal in response to the second clock signal CLKB. The second latching pair 220 latches the input signal from the second sampling pair 210 in response to the first clock signal CLK and outputs an output signal Y; YQ, YQB. The first current adjustor 230 adjusts a ratio between a third current flowing in the second sampling pair 210 and a fourth current flowing in the second lapping pair 220 according to the relative ratio between the sampling bias current ISb and the latching bias current ILb and varies the minimum power point oscillation frequency.

The bias adjustor 300 presets a reference current IREF and the reference current IREF is set to a sum of the sampling bias current ISb and the latching bias current ILb.

The bias adjustor 300 is configured such that the latching bias current ILb is varied by varying the sampling bias current ISb.

The bias adjustor 300 is configured such that the sampling bias current ISb is set greater than the latching bias current Lb to increase the minimum power point oscillating frequency and the sampling bias current ISb is set smaller than the latching bias current ILb to reduce the minimum power point oscillating frequency.

Also, the first sampling pair 110 is formed of a first transistor pair TP1 including first and second transistors M11 and M12. The first and second transistors M11 and M12 have drains connected to operating voltage Vdd terminals through resistors R11 and R12, respectively and configured as a differential pair. Here, the first transistor M11 transfers an input signal inputted to a gate in response to the first clock signal CLK to the drain of the second transistor M2 and the second transistor M12 transfers the input signal inputted to the gate in response to the first clock signal CLK to the drain of the first transistor M11.

The first latching pair 120 is formed of a second transistor pair TP2 including third and fourth transistors M13 and M14. The third M13 transistor has a drain connected to the drain of the first transistor M11 and the fourth transistor M14 has a drain connected to the drain of the second transistor M12. The third and fourth transistors M13 and M14 configured as a cross-coupled pair. Here, a signal inputted through the drain of the third transistor M13 is transferred to a gate of the fourth transistor M14 and a signal inputted through the drain of the fourth transistor M14 is transferred to a gate of the third transistor M13.

The second sampling pair 210 is formed of a third transistor pair TP3 including fifth and six transistors M15 and M16. The fifth and sixth transistors M15 and M16 have drains connected to operating voltage Vdd terminals through resistors R2 and R22, respectively and configured as a differential pair. Here, the fifth transistor M15 transfers an input signal inputted to a gate in response to the first clock signal CLK to the drain of the sixth transistor M16. The sixth transistor M16 transfers the input signal inputted to the gate in response to the gate in response to the first clock signal CLK to the drain of the fifth transistor M15.

The second latching pair 220 is formed of a fourth transistor pair TP4 including a seventh transistor M17 and an eighth transistor M18. The seventh transistor M17 has a drain connected to the drain of the fifth transistor M15. The eighth transistor M18 has a drain connected to the drain of the sixth transistor M16. The seventh and eighth transistors M17 and M18 are configured as a cross-coupled pair. Here, a signal inputted through the drain of the seventh transistor M17 is transferred to a gate of the eighth transistor M18 and a signal inputted through the drain of the eighth transistor M18 is transferred to a gate of the seventh transistor M17.

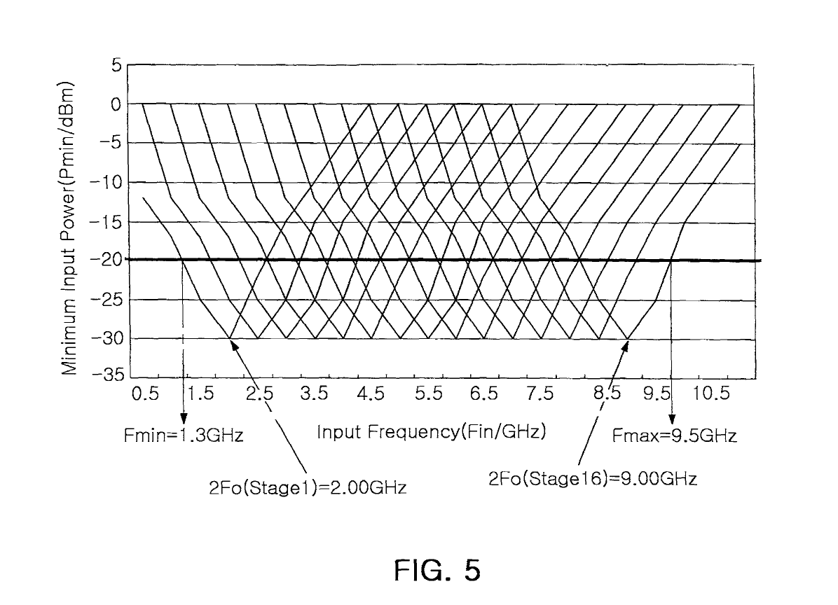

FIG. 5 is a multiple sensitivity curve illustrating a frequency divider according to an exemplary embodiment of the invention.

In the graph shown in FIG. 5, a vertical axis denotes an input power and a horizontal axis denotes an input frequency. The sensitivity characteristic curve has a plurality of power points by adjusting a ratio between a current flowing in a sampling pair and a current flowing in the latching pair in each latch.

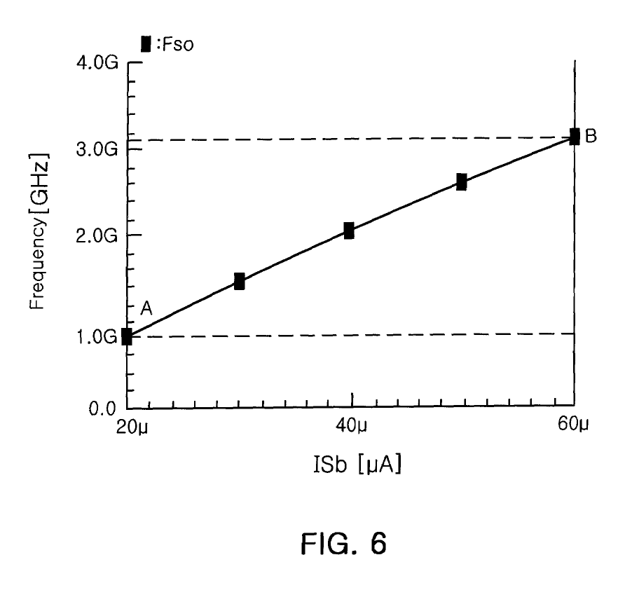

FIG. 6 is a graph illustrating an adjustment range of a sampling bias current ISb and a variable range of a frequency according to an exemplary embodiment of the invention. In the graph of FIG. 6, the adjustment range of the sampling bias current ISb and the variable range of the varying oscillating frequency are plotted.

Hereinafter, operation and effects of the present invention will be described in detail.

Operation of the frequency divider will be described according to the present invention with reference to FIGS. 4 to 6. First, referring to FIG. 4, the frequency divider of the present invention includes a first latch 100, a second latch 200 and a bias adjustor 300.

The first latch 100 samples and latches an input signal in response to a first clock signal CLK and a second clock signal CLKB having an inverse phase with respect to the first clock signal CLK.

Also, the second latch 200 is toggled with the first latch 100, and samples and latches the input signal in response to the first clock signal CLK and the second clock signal CLKB.

The bias adjustor 300 generates a sampling bias current ISb and a latching bias current ILb to supply to the first and second latches 100 and 200, respectively and adjusts a relative ratio between the sampling bias current ISb and the latching bias current ILb to vary a minimum power point oscillating frequency of the first and second latches 100 and 200.

The first latch 100 includes a first sampling pair 110, a first latching pair 120 and a first current adjustor 130.

The first sampling pair 110 samples the input signal in response to the first clock signal CLK to output to the first latching pair. Also, the first latching pair 120 latches the input signal from the first sampling pair 100 to an output terminal in response to the first clock signal CLK and the second clock signal CLKB having an inverse phase with respect to the first clock signal CLK.

Here, the first current adjustor 130 adjusts a ratio between a first current I10 flowing in the first sampling pair 110 and a second current I20 flowing in the first lapping pair 120 according to the relative ratio between the sampling bias current ISb and the latching bias current ILb to vary the minimum power point oscillating frequency.

Also, the first latch 200 includes a sampling pair 210, a second latching pair 220 and a second current adjustor 230.

The second sampling pair 210 samples the input signal in response to the second clock signal CLKB to output to the second latching pair 220. The second latching pair 220 latches the input signal from the second sampling pair 210 in response to the first clock signal CLK to an output terminal.

Here, the first current adjustor 230 adjusts a ratio between a third current I30 flowing in the second sampling pair 210 and a fourth current I40 flowing in the second lapping pair 220 according to the relative ratio between the sampling bias current ISb and the latching bias current ILb and varies the oscillation frequency of the minimum power point.

For this operation, the bias adjustor 300 of the present embodiment generates the sampling bias current ISb and the latching bias current ILb to supply to the first latch 100 and the second latch 200, respectively. Also, the bias adjustor 300 adjusts the relative ratio between the sampling bias current ISb and the latching bias current ILb to vary the minimum power point oscillating frequency of the first latch 100 and the second latch 200, respectively.

Meanwhile, the bias adjustor 300 presets a reference current IREF and the reference current IREF is set to a sum of the sampling bias current ISb and the latching bias current ILb, as shown in following Equation 1:

Iref=ISb+ILb Equation 1

Referring to the above Equation 1, when the bias adjustor 300 varies the sampling bias current ISb, the latching bias current ILb is automatically varied.

For example, in the bias adjustor 300, the sampling bias current ISb is set greater than the latching bias current ILb to increase the minimum power point oscillating frequency and the sampling bias current ISb is set smaller than the latching bias current ILb to reduce the minimum power point oscillating frequency.

As described above, the bias adjustor 300 of the present invention can adjust an operating frequency having a minimum power.

First, basic operations of the first sampling pair 110 and the first latching pair 120 will be described. As shown in FIG. 4, the first transistor pair TP1 of the first sampling pair 110 includes a first transistor M11 and a second transistor M12 configured as a differential pair.

Here, when the first clock signal CLK has a high level, the first transistor M11 of the first transistor pair TP1 transfers an input signal inputted to a gate thereof to a drain of the second transistor M2. The second transistor M12 transfers the input signal inputted to a gate thereof to the drain of the first transistor M11. That is, the first sampling pair 110 samples the input signal inputted from the second latching pair 220 of the present invention and transfers the sampled input signal to the first latching pair 120.

Meanwhile, when the first clock signal CLK has a low level, the first sampling pair 110 is turned off.

Moreover, as shown in FIG. 4, the second transistor pair TP2 of the first latching pair 120 includes third and fourth transistors M13 and M14 configured as a cross-coupled pair.

Here, when the first clock signal CLK has a high level, the first latching pair 120 is turned off. When the first clock signal CLK is a low level, the input signal inputted through a drain of the third transistor M13 is transferred to a gate of the fourth transistor M14. The input signal inputted through a drain of the fourth transistor M14 is transferred to a gate of the third transistor M13. That is, the first latching pair 120 latches the signal X; XQ and XQB inputted from the first sampling pair 110 to an output terminal.

Through this operation, the bias adjustor 300 is capable of adjusting currents of the first sampling pair 110 and the first latching pair 120, respectively and accordingly this allows for adjustment of the oscillating frequency having a minimum power point.

That is, the bias adjustor 300 adjusts the first current I10 of the first sampling pair 110 and the second current I20 of the first latching pair 120. Here, when the first current I10 and the second current I20 are adjusted by the bias adjustor 300, the first sampling pair 110 and the first latching pair 120 are capable of adjusting the oscillating frequency with minimum power point.

Next, basic operations of the second sampling pair 210 and the second latching pair 220 will be described.

As shown in FIG. 4, the third transistor pair TP3 of the second sampling pair 210 includes a fifth transistor M15 and a sixth transistor M16 configured as a differential pair.

Here, when the first clock signal CLK has a high level, the fifth transistor M15 transfers the input signal inputted to a gate in response to the first clock signal CLK to a drain of the sixth transistor M16. Also, the sixth transistor M15 transfers the input signal inputted to a gate in response to the first clock signal CLK to a drain of the fifth transistor M15. That is, the second sampling pair 210 samples the input signal inputted from the first latching pair 120 of the present invention to transfer to the second latching pair 220.

Meanwhile, when the first clock signal CLK has a low level, the second sampling pair 210 is turned off.

Furthermore, as shown in FIG. 4, the fourth transistor pair TP4 includes seventh and eighth transistors M17 and M18 configured as a cross-coupled pair.

Here, when the first clock signal CLK has a high level, the signal inputted through a drain of the seventh transistor M17 is transferred to a gate of the eighth transistor M18. Also, the signal inputted through a drain of the eighth transistor M18 is transferred to a gate of the seventh transistor M17. That is, the second latching pair 220 latches the signal Y; YQ and YQB inputted from the second sampling pair 210 to the output terminal.

Through this process, the bias adjustor 300 adjusts currents of the second sampling pair 210 and the second latching pair 220, respectively and accordingly this allows for adjustment of an oscillating frequency Fo with minimum power point.

That is, the bias adjustor 300 adjusts a third current I30 of the second sampling pair 210 and a fourth current I40 of the second latching pair 220. Here, when the bias adjustor 300 adjusts the third current I30 and the fourth current I40, an oscillating frequency with minimum power point can be adjusted in the second sampling pair 210 and the second latching pair 220.

Meanwhile, referring to FIGS. 4 to 6, in the frequency divider employing a pseudo-differential latch structure of the present invention, four output terminals XQ, XQB, YQ, and YQB each output a signal under an identical principle. Thus, the oscillating frequency will be described based on the XQ output terminal.

As described above, the oscillating frequency Fo of the frequency divider of the present embodiment is determined Fo=1/(RC) by an overall resistance Rtot shown in the XQ output terminal and an overall capacitance Ctot shown in the XQ output terminal, as shown in following Equation 2. The overall capacitance Ctot is determined by each of parasitic capacitance of the second to fourth transistors M12, M13, and M14 and load resistors R11 and R12:

$$Fo = \frac{1}{Rtot \cdot Ctot} , \qquad Equation 2$$

where Rtot denotes an overall resistance of the XQ output terminal, and Ctot denotes an overall capacitance of the XQ output terminal. This overall capacitance Ctot is determined by first to third parasitic capacitance of second to fourth transistors M12 to M14 and a fourth parasitic capacitance of the load resistors R11, and R12. The overall capacitance Ctot is represented by following Equation 2:

C=first parasitic capacitance (by M12)+second parasitic capacitance (by M13)+third parasitic capacitance (by M14)+fourth parasitic capacitance (by load resistor) Equation 3

The current of the first sampling pair and the current of the first latching pair are determined by the channel with of the second, third and fourth transistors M12, M13, and M14 and resistances of the resistors R11 and R12. Accordingly, the oscillating frequency is determined by an overall capacitance Ctot and an overall resistance Rtot.

Here, the resistance is changed by the current flowing in the first sampling pair and the current flowing in the latching pair, respectively. Therefore, the current is varied to adjust the oscillating frequency. The principle of varying the resistance by adjusting the current will be described hereinbelow.

First, when a voltage of the XQ output terminal of the frequency divider of the present invention is denoted with “Vout” and the current outputted through the XQ output terminal is denoted with “Itot”, the resistance Rtot at the XQ output terminal is represented by following Equation 4 and “Itot” is obtained from following Equation 5:

$$Rtot = \frac{Vout}{Itot} \qquad Equation 4$$

Itot=I21+I22+I22

I21=Vout/ro14+(−gm14*Vout)

I22=Vout/R

I23=Vout/ro12 Equation 5

where Vout denotes a voltage of the XQ output terminal, ro14 denotes an output impedance of the fourth transistor M14, gm14 is a transconductance of the fourth transistor M14, R is load resistance and ro12 is an output impedance of the second transistor M12.

When the Equation 5 is applied to Equation 4, following Equation 6 is derived.

$$Rtot = \frac{Vout}{Itot} = \frac{1}{\frac{1}{ro 14} + \frac{1}{ro 12} + \frac{1}{R} - gm 14} \qquad Equation 6$$

In the above Equation 6, gm14 is proportional to rm sqrt{I}, and thus an increase in the current of the first latching pair leads to a decrease in the oscillating frequency.

That is, with an increase It in the current of the first latching pair, a transconductance gm14 of the fourth transistor M14 is increased gm↑. With an increase in the transconductance gm14, the resistance Rtot at the XQ output terminal is increased Rtot↑. Accordingly, this reduces the oscillating frequency Fo.

Referring to FIG. 5, the frequency divider of the present invention has an operating range of about 156% with respect to an output of a voltage control oscillator with an input power of −20 dBm when designed such that an input frequency 2Fo is changed from 2.00 GHz to 9.00 GHz in response to a switching signal.

That is, as shown in the graph, adjusting the currents flowing in the sampling pair and the lapping pair, respectively leads to a plurality of oscillating frequencies with minimum power point.

For example, as for an input frequency having a minimum power point that is twice the output frequency Fo, there are a plurality of input frequencies whose minimum power point ranges from 1.73 GHz which is twice the output frequency of 0.866 GHz to 9.7 GHz which is twice the output frequency of 4.533 GHz.

According to the present invention, through the bias adjustor 300, a ratio between the sampling currents and the latching currents of the first latch 100 and second latch 200 is adjusted to vary the minimum power point oscillating frequency.

As set forth above, according to exemplary embodiments of the invention, in a frequency divider dividing a frequency by two using a latch structure, a ratio between a sampling pair current and a latching pair current is changed using a bias current to change an operating frequency. Also, the frequency divider operates in a wide range while occupying significantly less area and consuming much less current.

While the present invention has been shown and described in connection with the exemplary embodiments, it will be apparent to those skilled in the art that modifications and variations can be made without departing from the spirit and scope of the invention as defined by the appended claims.

What is claimed is:

1. A frequency divider using a latch structure comprising:
a first latch sampling and latching an input signal in response to a first clock signal and a second clock signal having an inverse phase with respect to the first clock signal;
a second latch toggled with the first latch, the second latch sampling and latching the input signal in response to the first and second clock signals;
a bias adjustor generating a sampling bias current and a latching bias current to supply to the first and second latches, respectively and adjusting a relative ratio between the sampling bias current and the latching bias current to vary a minimum power point oscillating frequency of the first and second latches.

2. The frequency divider of claim 1, wherein the first latch comprises:
a first sampling pair sampling the input signal in response to the first clock signal;
a first latching pair latching the input signal from the first sampling pair in response to the second clock signal and outputting an output signal; and
a first current adjustor adjusting a ratio between a first current flowing in the first sampling pair and a second current flowing in the first latching pair according to the relative ratio between the sampling bias current and the latching bias current to vary the minimum power point oscillating frequency.

3. The frequency divider of claim 2, wherein the second latch comprises:
a second sampling pair sampling and outputting the input signal in response to the second clock signal;
a second latching pair latching the input signal from the second sampling pair in response to the first clock signal and outputting an output signal; and
a first current adjustor adjusting a ratio between a third current flowing in the second sampling pair and a fourth current flowing in the second latching pair according to the relative ratio between the sampling bias current and the latching bias current and varying the minimum power point oscillation frequency.

4. The frequency divider of claim 3, wherein the bias adjustor presets a reference current and the reference current is set to a sum of the sampling bias current and the latching bias current.

5. The frequency divider of claim 4, wherein the bias adjustor is configured such that the latching bias current is varied by varying the sampling bias current.

6. The frequency divider of claim 4, wherein the bias adjustor is configured such that the sampling bias current is set greater than the latching bias current to increase the minimum power point oscillating frequency and the sampling bias current is set smaller than the latching bias current to reduce the minimum power point oscillating frequency.

7. The frequency divider of claim 4, wherein the first sampling pair comprises a first transistor pair including first and second transistors, the first and second transistors having drains connected to operating voltage terminals through resistors, respectively and configured as a differential pair,
wherein the first transistor transfers an input signal inputted to a gate in response to the first clock signal to the drain of the second transistor, and the second transistor transfers the input signal inputted to the gate in response to the first clock signal to the drain of the first transistor.

8. The frequency divider of claim 7, wherein the first latching pair comprises a second transistor pair including a third transistor having a drain connected to the drain of the first transistor and a fourth transistor having a drain connected to the drain of the second transistor, the third and fourth configured as a cross-coupled pair,
wherein a signal inputted through the drain of the third transistor is transferred to a gate of the fourth transistor and a signal inputted through the drain of the fourth transistor is transferred to a gate of the third transistor.

9. The frequency divider of claim 8, wherein the second sampling pair comprises a third transistor pair including fifth and sixth transistors, the fifth and sixth transistors having drains connected to operating voltage terminals through resistors, respectively and configured as a differential pair,
wherein the fifth transistor transfers an input signal inputted to a gate in response to the first clock signal to the drain of the sixth transistor, and the sixth transistor transfers the input signal inputted to the gate in response to the first clock signal to the drain of the fifth transistor.

10. The frequency divider of claim 9, wherein the second latching pair comprises a fourth transistor pair including a seventh transistor having a drain connected to the drain of the fifth transistor and an eighth transistor having a drain connected to the drain of the sixth transistor, the seventh and eighth transistors configured as a cross-coupled pair,
wherein a signal inputted through the drain of the seventh transistor is transferred to a gate of the eighth transistor and a signal inputted through the drain of the eighth transistor is transferred to a gate of the seventh transistor.
